(19) United States
(12) Patent Application Publication
(10) Pub. No.: US 2025/0354247 A1
(43) Pub. Date: Nov. 20, 2025

(54) DEPOSITION APPARATUS AND METHOD OF MANUFACTURING DISPLAY DEVICE USING THE SAME

(71) Applicant: Samsung Display Co., LTD., Yongin-si (KR)

(72) Inventors: Jin Yong LEE, Yongin-si (KR); Kyong Tae YU, Yongin-si (KR); Yeon Woo LEE, Yongin-si (KR); Il Soo LEE, Yongin-si (KR)

(73) Assignee: Samsung Display Co., LTD., Yongin-si (KR)

(21) Appl. No.: 19/030,812

(22) Filed: Jan. 17, 2025

(30) Foreign Application Priority Data
May 16, 2024 (KR) 10-2024-0063581

(51) Int. Cl. C23C 14/04; H10K 71/16

(52) U.S. Cl. CPC C23C 14/042; H10K 71/166

(57) ABSTRACT

A deposition apparatus includes a deposition source, a mask disposed between a first substrate and the deposition source, a mask support disposed between the deposition source and the mask and supporting at least a portion of the mask, and a magnetic member disposed on the first substrate and fixing the mask support with magnetic force. The magnetic member includes a plurality of magnets extending in a first direction. The mask support extends in a second direction perpendicular to the first direction.

### CROSS-REFERENCE TO RELATED APPLICATION(S)

This application claims priority to and benefits of Korean Patent Application No. 10-2024-0063581 under 35 U.S.C. § 119, filed on May 16, 2024, in the Korean Intellectual Property Office (KIPO), the entire contents of which are incorporated herein by reference.

### BACKGROUND

### 1. Technical Field

Embodiments relate to a deposition apparatus and a method of manufacturing a display device including the same.

### 2. Description of the Related Art

Wearable devices in which a focus is formed at a distance close to the user's eyes have been developed in the form of glasses or a helmet. For example, the wearable device may be a head mounted display (HMD) device or AR glasses. The wearable device provides an augmented reality (hereinafter, referred to as “AR”) screen or a virtual reality (hereinafter, referred to as “VR”) screen to a user.

The wearable devices such as the HMD device or the AR glasses require a display specification of approximately 3000 PPI (pixels per inch) or more so that a user may use it for a long time without dizziness. To this end, organic light-emitting diode on silicon (OLEDoS) technology that is a high-resolution small organic light-emitting display device is emerging. The organic light-emitting diode on silicon (OLEDoS) is technology for disposing an organic light-emitting diode (OLED) on a semiconductor wafer substrate on which a complementary metal oxide semiconductor (CMOS) is disposed.

A high-resolution deposition mask is required to manufacture a high-resolution display panel of approximately 3000 PPI or more. As a deposition mask for manufacturing OLEDoS display panels, a mask in which an inorganic film is deposited on a silicon substrate and the deposited inorganic film is patterned to form a mask membrane is being studied. However, the gap between the mask and the deposition surface of the deposition substrate increases due to the weight of the mask membrane formed of an inorganic film. The gap is pointed out as the cause of shadow defects or color mixing defects.

### SUMMARY

Embodiments provide a deposition apparatus capable of reducing shadow defects or color mixing defects by reducing the gap between a deposition substrate and a mask, and a method of manufacturing a display device including the same.

However, embodiments are not limited to those set forth herein. The above and other embodiments will be apparent to one of ordinary skill in the art to which the disclosure pertains by referencing the detailed description of the disclosure given below.

According to an embodiment, a deposition apparatus may include a deposition source, a mask disposed between a first substrate and the deposition source, a mask support disposed between the deposition source and the mask and supporting at least a portion of the mask, and a magnetic member disposed on the first substrate and fixing the mask support with magnetic force. The magnetic member may include a plurality of magnets extending in a first direction. The mask support may extend in a second direction perpendicular to the first direction.

The mask may include a silicon substrate including a plurality of cell regions, an outer frame region disposed on an outermost edge of the plurality of cell regions, and a mask lip region disposed at a periphery of the plurality of cell regions, and a mask membrane disposed to correspond to the plurality of cell regions on the silicon substrate.

The mask membrane may include an inorganic film.

The inorganic film may include at least one of silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ), and x may be a natural number.

The plurality of cell regions may be arranged in a matrix form. The mask support may include a plurality of first magnetic lifters disposed to intersect between the plurality of cell regions, and a plurality of second magnetic lifters disposed on both sides of the plurality of first magnetic lifters and supporting the outer frame region.

Each of the plurality of first magnetic lifters may have a first width in the first direction. Each of the plurality of second magnetic lifters may have the first width in the first direction.

Each of the plurality of first magnetic lifters may have a first width in the first direction. Each of the plurality of second magnetic lifters may have a second width smaller than the first width in the first direction.

The magnetic member may include a first magnet having a first polarity and extending in the first direction, and a second magnet having a second polarity and extending in the first direction.

The first magnet and the second magnet may be alternately arranged in the second direction.

The mask support may include a ferromagnetic substance.

A method of manufacturing a display device, the method may include placing a first substrate on a surface of a mask inside a chamber of a deposition apparatus, placing a deposition source to face a surface of the first substrate, and vaporizing a deposition material included in the deposition source, passing the deposition material through the mask, and depositing the deposition material on the first substrate. The deposition apparatus may support at least a portion of the mask, and include a mask support disposed between the deposition source and the mask and supporting the at least a portion of the mask, and a magnetic member disposed on the first substrate and fixing the mask support. The magnetic member may include a plurality of magnets extending in a first direction. The mask support may extend in a second direction perpendicular to the first direction.

The mask may include a silicon substrate including a plurality of cell regions, an outer frame region disposed on an outermost edge of the plurality of cell regions, and a mask lip region disposed at a periphery of the plurality of cell regions, and a mask membrane disposed to correspond to the plurality of cell regions on the silicon substrate.

The mask membrane may include an inorganic film.

The inorganic film may include at least one of silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ), and x may be a natural number.

The plurality of cell regions may be arranged in a matrix form. The mask support may include a plurality of first magnetic lifters disposed to intersect between the plurality of cell regions, and a plurality of second magnetic lifters disposed on both sides of the plurality of first magnetic lifters and supporting the outer frame region.

Each of the plurality of first magnetic lifters may have a first width in the first direction. Each of the plurality of second magnetic lifters may have the first width in the first direction.

Each of the plurality of first magnetic lifters may have a first width in the first direction. Each of the plurality of second magnetic lifters may have a second width smaller than the first width in the first direction.

The magnetic member may include a first magnet having a first polarity and extending in the first direction, and a second magnet having a second polarity and extending in the first direction.

The first magnet and the second magnet may be alternately arranged in the second direction.

The mask support may include a ferromagnetic substance.

According to an embodiment, it may be possible to reduce shadow defects or color mixing defects by reducing the gap between the deposition substrate and the mask.

### BRIEF DESCRIPTION OF THE DRAWINGS

The accompanying drawings, which are included to provide a further understanding of the disclosure, illustrate embodiments in which:

FIG. 1 is an exploded perspective view showing a display device according to one embodiment;

FIG. 2 is a schematic block diagram illustrating a display device according to one embodiment;

FIG. 3 is a schematic diagram of an equivalent circuit of a first sub-pixel according to one embodiment;

FIG. 4 is a schematic diagram illustrating a layout of a display panel according to one embodiment;

FIGS. 5 and 6 are schematic diagrams illustrating a layout of the display area of FIG. 4 according to embodiments;

FIG. 7 is a schematic cross-sectional view illustrating an embodiment of a display panel taken along line I1-I1′ of FIG. 5;

FIG. 8 is a perspective view illustrating a head mounted display according to one embodiment;

FIG. 9 is an exploded perspective view illustrating an embodiment of the head mounted display of FIG. 8;

FIG. 10 is a perspective view illustrating a head mounted display according to one embodiment;

FIG. 11 is a perspective view of a mask according to one embodiment;

FIG. 12 is a schematic plan view of a mask according to one embodiment;

FIGS. 13 to 21 are schematic cross-sectional views illustrating a method of manufacturing a mask according to one embodiment;

FIG. 22 is a schematic diagram schematically illustrating a deposition apparatus according to one embodiment;

FIG. 23 is an exploded perspective view illustrating a deposition apparatus according to one embodiment;

FIG. 24 is a schematic diagram of a magnetic member and a mask support according to one embodiment; and

FIG. 25 is a schematic diagram of a magnetic member and a mask support according to another embodiment.

### DETAILED DESCRIPTION OF THE EMBODIMENTS

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on another layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within about ±30%, 20%, 10%, 5% of the stated value.

In the description, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the description, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the description.

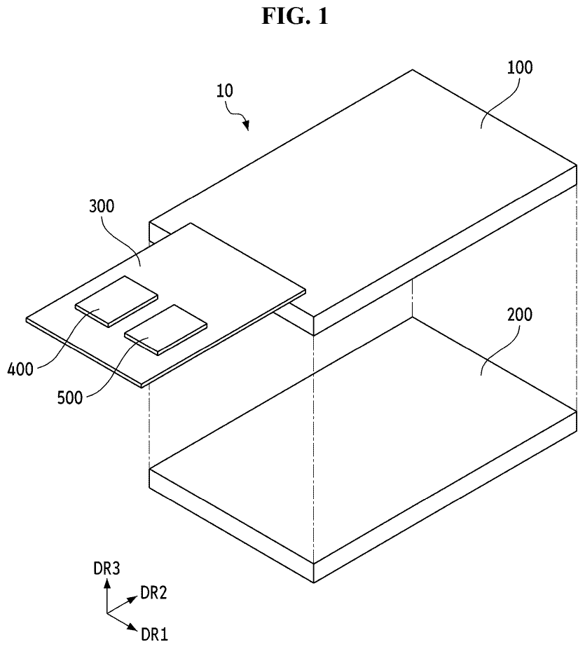

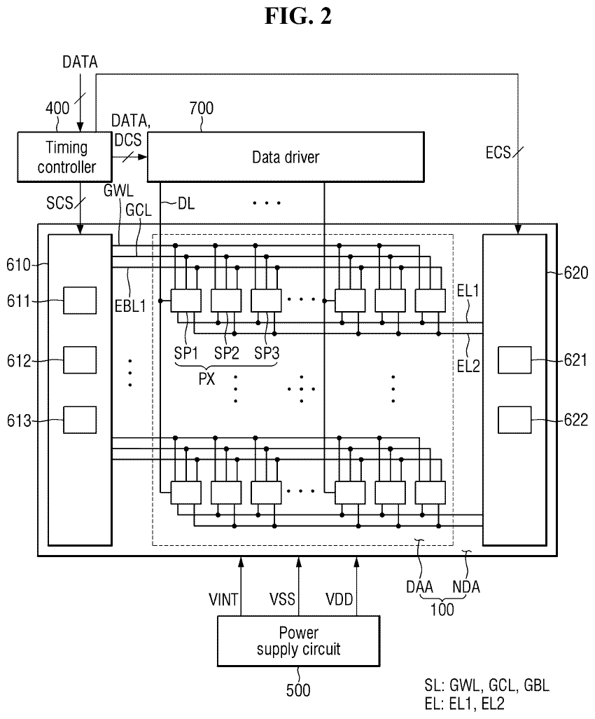

FIG. 1 is an exploded perspective view showing a display device according to one embodiment. FIG. 2 is a schematic block diagram illustrating a display device according to one embodiment.

Referring to FIGS. 1 and 2, a display device 10 according to one embodiment may be a device displaying a moving image or a still image. The display device 10 according to one embodiment may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 according to one embodiment may be applied as a display unit of a television, a laptop, a monitor, a billboard, or an Internet-of-Things (IoT) terminal. For example, the display device 10 according to one embodiment may be applied to a smart watch, a watch phone, a head mounted display (HMD) for implementing virtual reality and augmented reality, and the like.

The display device 10 according to one embodiment may include a display panel 100, a heat dissipation layer 200, a circuit board 300, a timing controller 400, and a power supply circuit 500.

The display panel 100 may have a shape similar to a quadrilateral shape in a plan view. For example, the display panel 100 may have a planar shape similar to a quadrilateral shape having a short side of a first direction DR1 and a long side of a second direction DR2 intersecting the first direction DR1. In the display panel 100, a corner where a short side in the first direction DR1 and a long side in the second direction DR2 meet may be right-angled or rounded with a curvature. The planar shape of the display panel 100 is not limited to a quadrilateral shape, and the display panel 100 may have a shape similar to another polygonal shape, a circular shape, or an elliptical shape. The planar shape of the display device 10 may conform to the planar shape of the display panel 100, but the disclosure is not limited thereto. The display panel 100 may include a display area DAA displaying an image and a non- display area NDA not displaying an image as shown in FIG. 2.

The display area DAA may include multiple pixels PX, multiple scan lines SL, multiple emission control lines EL, and multiple data lines DL.

The pixels PX may be arranged in a matrix form in the first direction DR1 and the second direction DR2. The scan lines SL and the emission control lines EL may extend in the first direction DR1 and arranged in the second direction DR2. The data lines DL may extend in the second direction DR2 and may be arranged in the first direction DR1.

The scan lines SL may include multiple write scan lines GWL, multiple control scan lines GCL, and multiple bias scan lines GBL. The emission control lines EL may include multiple first emission control lines EL1 and multiple second emission control lines EL2.

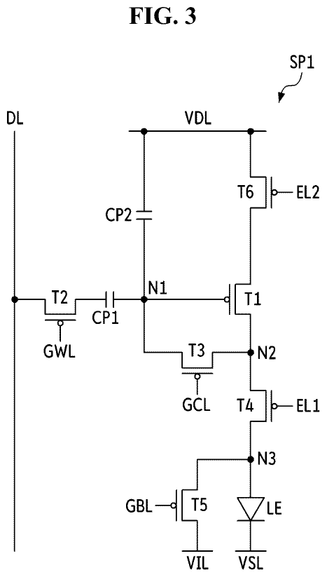

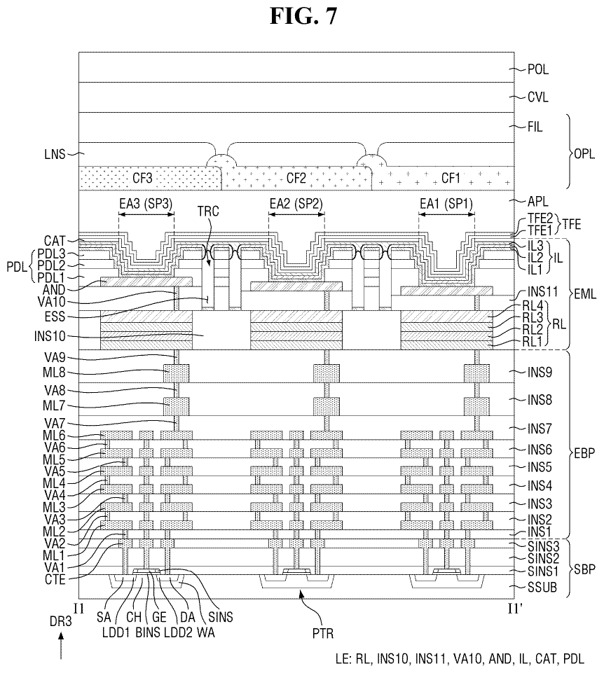

The pixels PX include multiple sub-pixels SP1, SP2, and SP3. The sub-pixels SP1, SP2, and SP3 may include multiple pixel transistors as shown in FIG. 3, and the pixel transistors may be formed by a semiconductor process and disposed on a semiconductor substrate SSUB (see FIG. 7). For example, the pixel transistors of a data driver 700 may be formed of complementary metal oxide semiconductor (CMOS).

Each of the sub-pixels SP1, SP2, and SP3 may be connected to one of the write scan lines GWL, one of the control scan lines GCL, one of the bias scan lines GBL, one of the first emission control lines EL1, one of the second emission control lines EL2, and one of the data lines DL. Each of the sub-pixels SP1, SP2, and SP3 may receive a data voltage from the data line DL in response to a write scan signal from the write scan line GWL, and emit light from the light-emitting element according to the data voltage.

The non-display area NDA may include a scan driver 610, an emission driver 620, and a data driver 700.

The scan driver 610 may include multiple scan transistors, and the emission driver 620 may include multiple light-emitting transistors. The scan transistors and the light-emitting transistors may be formed on the semiconductor substrate SSUB (see FIG. 7) through a semiconductor process. For example, the scan transistors and the light-emitting transistors may be formed of CMOS. Although it is illustrated in FIG. 2 that the scan driver 610 is disposed on the left side of the display area DAA and the emission driver 620 is disposed on the right side of the display area DAA, the disclosure is not limited thereto. For example, the scan driver 610 and the emission driver 620 may be disposed on both the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing controller 400. The write scan signal output unit 611 may generate write scan signals according to the scan timing control signal SCS of the timing controller 400 and output the write scan signals sequentially to the write scan lines GWL. The control scan signal output unit 612 may generate control scan signals in response to the scan timing control signal SCS and sequentially output the control scan signals to the control scan lines GCL. The bias scan signal output unit 613 may generate bias scan signals according to the scan timing control signal SCS and output the bias scan signals sequentially to the bias scan lines GBL.

The emission driver 620 may include a first emission control driver 621 and a second emission control driver 622. Each of the first emission control driver 621 and the second emission control driver 622 may receive an emission timing control signal ECS from the timing controller 400. The first emission control driver 621 may generate first emission control signals according to the emission timing control signal ECS and sequentially output the first emission control signals to the first emission control lines EL1. The second emission control driver 622 may generate second emission control signals according to the emission timing control signal ECS and sequentially output the second emission control signals to the second emission control lines EL2.

The data driver 700 may include multiple data transistors, and the data transistors may be formed on the semiconductor substrate SSUB (see FIG. 7) through a semiconductor process. For example, the data transistors may be formed of CMOS.

The data driver 700 may receive digital video data DATA and a data timing control signal DCS from the timing controller 400. The data driver 700 may convert the digital video data DATA into analog data voltages according to the data timing control signal DCS and outputs the analog data voltages to the data lines DL. The sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is the thickness direction of the display panel 100. The heat dissipation layer 200 may be disposed on a surface of the display panel 100, for example, on the rear surface of the display panel 100. The heat dissipation layer 200 may dissipate heat generated from the display panel 100. The heat dissipation layer 200 may include a metal layer such as graphite, silver (Ag), copper (Cu), or aluminum (Al) having high thermal conductivity.

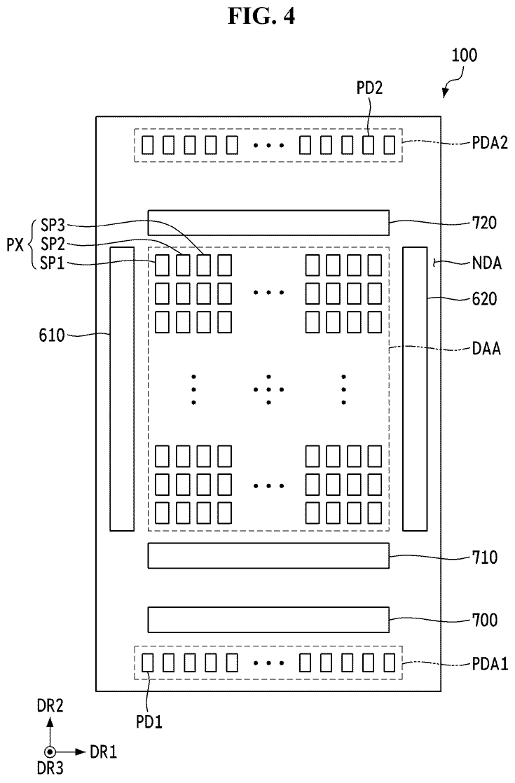

The circuit board 300 may be electrically connected to multiple first pads PD1 (see FIG. 4) of a first pad portion PDA1 (see FIG. 4) of the display panel 100 by using a conductive adhesive member such as an anisotropic conductive film. The circuit board 300 may be a flexible printed circuit board including a flexible material, or a flexible film. Although the circuit board 300 is illustrated in FIG. 1 as being unfolded, the circuit board 300 may be bendable. An end of the circuit board 300 may be disposed on the rear surface of the display panel 100 and/or the rear surface of the heat dissipation layer 200. The end of the circuit board 300 may be an opposite end of another end of the circuit board 300 connected to the first pads PD1 (see FIG. 4) of the first pad portion PDA1 (see FIG. 4) of the display panel 100 by using a conductive adhesive member.

The timing controller 400 may receive digital video data DATA and timing signals inputted from the outside. The timing controller 400 may generate the scan timing control signal SCS, the emission timing control signal ECS, and the data timing control signal DCS for controlling the display panel 100 in response to the timing signals. The timing controller 400 may output the scan timing control signal SCS to the scan driver 610, and output the emission timing control signal ECS to the emission driver 620. The timing controller 400 may output the digital video data DATA and the data timing control signal DCS to the data driver 700.

The power supply circuit 500 may generate multiple panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described below in conjunction with FIG. 3.

Each of the timing controller 400 and the power supply circuit 500 may be formed as an integrated circuit (IC) and attached to a surface of the circuit board 300. The scan timing control signal SCS, the emission timing control signal ECS, the digital video data DATA, and the data timing control signal DCS of the timing controller 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In another embodiment, similarly to the scan driver 610, the emission driver 620, and the data driver 700, each of the timing controller 400 and the power supply circuit 500 may be disposed in the non-display area NDA of the display panel 100. The timing controller 400 may include multiple timing transistors, and each power supply circuit 500 may include multiple power transistors. The timing transistors and the power transistors may be formed on the semiconductor substrate SSUB (see FIG. 7) through a semiconductor process. For example, the timing transistors and the power transistors may be formed of CMOS. Each of the timing controller 400 and the power supply circuit 500 may be disposed between the data driver 700 and the first pad portion PDA1 (see FIG. 4).

FIG. 3 is a schematic diagram of an equivalent circuit of a first sub-pixel according to one embodiment.

Referring to FIG. 3, the first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. For example, the first driving voltage line VSL may be a low potential voltage line, the second driving voltage line VDL may be a high potential voltage line, and the third driving voltage line VIL may be an initialization voltage line. The first driving voltage VSS may be lower than the third driving voltage VINT. The second driving voltage VDD may be higher than the third driving voltage VINT.

The first sub-pixel SP1 may include multiple transistors T1 to T6, a light-emitting element LE, a first capacitor CP1, and a second capacitor CP2.

The light-emitting element LE may emit light in response to a driving current flowing through the channel of the first transistor T1. The emission amount of the light-emitting element LE may be proportional to the driving current. The light-emitting element LE may be disposed between a fourth transistor T4 and the first driving voltage line VSL. The first electrode of the light-emitting element LE may be connected to the drain electrode of the fourth transistor T4, and the second electrode thereof may be connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer disposed between the first electrode and the second electrode, but the disclosure is not limited thereto. For example, the light-emitting element LE may be an inorganic light-emitting element including a first electrode, a second electrode, and an inorganic semiconductor disposed between the first electrode and the second electrode, and the light-emitting element LE may be a micro light-emitting diode.

The first transistor T1 may be a driving transistor that controls a source-drain current (hereinafter also referred to as “driving current”) flowing between the source electrode and the drain electrode of the first transistor T1 according to a voltage applied to the gate electrode of the first transistor T1. The first transistor T1 may include a gate electrode connected to a first node N1, a source electrode connected to the drain electrode of a sixth transistor T6, and a drain electrode connected to a second node N2.

A second transistor T2 may be disposed between an electrode of the first capacitor CP1 and the data line DL. The second transistor T2 may be turned on by the write scan signal of the write scan line GWL to connect the electrode of the first capacitor CPI to the data line DL. Accordingly, the data voltage of the data line DL may be applied to the electrode of the first capacitor CP1. The second transistor T2 may include a gate electrode connected to the write scan line GWL, a source electrode connected to the data line DL, and a drain electrode connected to the electrode of the first capacitor CP1.

A third transistor T3 may be disposed between the first node N1 and the second node N2. The third transistor T3 may be turned on by the write control signal of the write control line GCL to connect the first node N1 to the second node N2. In case that the gate electrode and the source electrode of the first transistor T1 are connected, the first transistor T1 may operate like a diode. The third transistor T3 may include a gate electrode connected to the write control line GCL, a source electrode connected to the second node N2, and a drain electrode connected to the first node N1.

The fourth transistor T4 may be connected between the second node N2 and a third node N3. The fourth transistor T4 may be turned on by the first emission control signal of the first emission control line EL1 to connect the second node N2 to the third node N3. Accordingly, the driving current of the first transistor T1 may be supplied to the light-emitting element LE. The fourth transistor T4 may include a gate electrode connected to the first emission control line EL1, a source electrode connected to the second node N2, and a drain electrode connected to the third node N3.

A fifth transistor T5 may be disposed between the third node N3 and the third driving voltage line VIL. The fifth transistor T5 may be turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE. The fifth transistor T5 may include a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 may be turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 may be formed between the first node N1 and the drain electrode of the second transistor T2. The first capacitor CP1 may include an electrode connected to the drain electrode of the second transistor T2 and another electrode connected to the first node N1.

The second capacitor CP2 may be formed between the gate electrode of the first transistor T1 and the second driving voltage line VDL. The second capacitor CP2 may include an electrode connected to the gate electrode of the first transistor T1 and another electrode connected to the second driving voltage line VDL.

The first node N1 may be a junction between the gate electrode of the first transistor T1, the drain electrode of the third transistor T3, the another electrode of the first capacitor CP1, and the electrode of the second capacitor CP2. The second node N2 may be a junction between the drain electrode of the first transistor T1, the source electrode of the third transistor T3, and the source electrode of the fourth transistor T4. The third node N3 may be a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the disclosure is not limited thereto. In another embodiment, each of the first to sixth transistors T1 to T6 may be an N-type MOSFET. In another embodiment, some of the first to sixth transistors T1 to T6 may be P-type MOSFETs, and each of the remaining transistors may be an N-type MOSFET.

Although it is illustrated in FIG. 3 that the first sub-pixel SP1 includes six transistors T1 to T6 and two capacitors C1 and C2, it should be noted that the first sub-pixel SP1 is not limited to the embodiment shown in FIG. 3. For example, the number of transistors and the number of capacitors of the first sub-pixel SP1 are not limited to the embodiment shown in FIG. 3.

Further, the circuit diagram of the second sub-pixel SP2 and the circuit diagram of the third sub-pixel SP3 may be substantially the same as the circuit diagram of the first sub-pixel SP1 described in conjunction with FIG. 3. Therefore, the description of the circuit diagram of the second sub-pixel SP2 and the circuit diagram of the third sub-pixel SP3 is not repeated in the disclosure.

FIG. 4 is a schematic diagram illustrating a layout of a display panel according to one embodiment.

Referring to FIG. 4, the display area DAA of the display panel 100 according to one embodiment may include the pixels PX arranged in a matrix form. The non-display area NDA of the display panel 100 according to one embodiment may include the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on a side of the display area DAA in the first direction DR1, and the emission driver 620 may be disposed on another side of the display area DAA in the first direction DR1. For example, the scan driver 610 may be disposed on the left side of the display area DAA, and the emission driver 620 may be disposed on the right side of the display area DAA. However, the disclosure is not limited thereto, and the scan driver 610 and the emission driver 620 may be disposed on both the first side and the second side of the display area DAA.

The first pad portion PDA1 may include the first pads PD1 connected to pads or bumps of the circuit board 300 through a conductive adhesive member. The first pad portion PDA1 may be disposed on the third side of the display area DAA. For example, the first pad portion PDA1 may be disposed on a side of the display area DAA in the second direction DR2.

The first pad portion PDA1 may be disposed outside the data driver 700 in the second direction DR2. For example, the first pad portion PDA1 may be disposed closer to the edge of the display panel 100 than the data driver 700.

The second pad portion PDA2 may include multiple second pads PD2 corresponding to inspection pads that test whether the display panel 100 operates normally. The second pads PD2 may be connected to a jig or a probe pin during an inspection process, or may be connected to a circuit board for inspection. The circuit board for inspection may be a printed circuit board made of a rigid material or a flexible printed circuit board made of a flexible material.

The first distribution circuit 710 may distribute data voltages applied through the first pad portion PDA1 to the data lines DL. For example, the first distribution circuit 710 may distribute the data voltages applied through a first pad PD1 of the first pad portion PDA1 to the P (P is a positive integer of 2 or more) data lines DL, and as a result, the number of the first pads PD1 may be reduced. The first distribution circuit 710 may be disposed on the third side of the display area DAA of the display panel 100. For example, the first distribution circuit 710 may be disposed on a side of the display area DAA in the second direction DR2. For example, the first distribution circuit 710 may be disposed on the lower side of the display area DAA.

The second distribution circuit 720 may distribute signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the another side of the display area DAA in the second direction DR2. For example, the second distribution circuit 720 may be disposed on the upper side of the display area DAA.

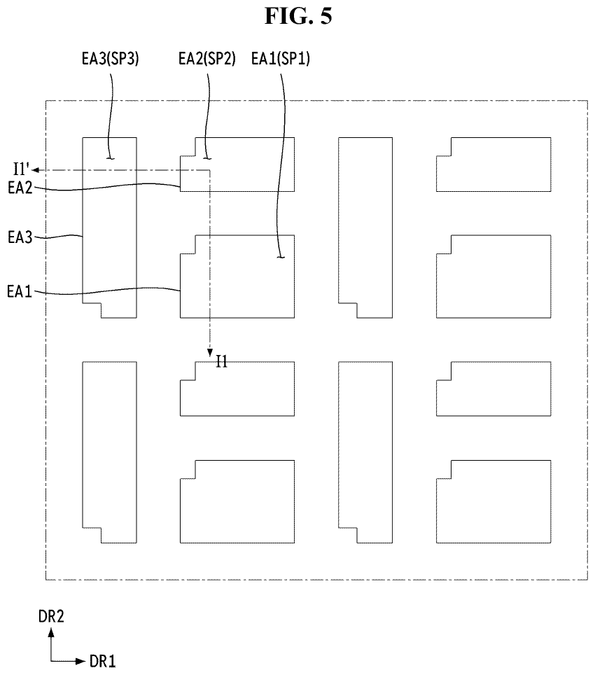

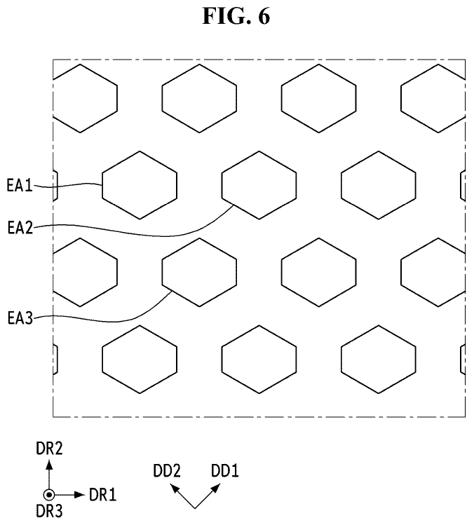

FIGS. 5 and 6 are schematic diagrams illustrating a layout of the display area of FIG. 4 according to embodiments.

Referring to FIGS. 5 and 6, each of the pixels PX may include a first emission area EA1 that is an emission area of the first sub-pixel SP1, a second emission area EA2 that is an emission area of the second sub-pixel SP2, and a third emission area EA3 that is an emission area of the third sub-pixel SP3.

Each of the first emission area EA1, the second emission area EA2, and the third emission area EA3 may have a polygonal, circular, elliptical, or atypical shape in a plan view.

The maximum length of the third emission area EA3 in the first direction DR1 may be less than the maximum length of the first emission area EA1 in the first direction DR1 and the maximum length of the second emission area EA2 in the first direction DR1. The maximum length of the first emission area EA1 in the first direction DR1 and the maximum length of the second emission area EA2 in the first direction DR1 may be substantially the same.

The maximum length of the third emission area EA3 in the second direction DR2 may be greater than the maximum length of the first emission area EA1 in the second direction DR2 and the maximum length of the second emission area EA2 in the second direction DR2. The maximum length of the first emission area EA1 in the second direction DR2 may be greater than the maximum length of the second emission area EA2 in the second direction DR2.

The first emission area EA1, the second emission area EA2, and the third emission area EA3 may have, in a plan view, a hexagonal shape formed of six straight lines as shown in FIGS. 5 and 6, but the disclosure is not limited thereto. The first emission area EA1, the second emission area EA2, and the third emission area EA3 may have a polygonal shape other than a hexagon, a circular shape, an elliptical shape, or an atypical shape in a plan view.

As shown in FIG. 5, in each of the pixels PX, the first emission area EA1 and the second emission area EA2 may be adjacent to each other in the second direction DR2. In an embodiment, the first emission area EA1 and the third emission area EA3 may be adjacent to each other in the first direction DR1. In an embodiment, the second emission area EA2 and the third emission area EA3 may be adjacent to each other in the first direction DR1. The area of the first emission area EA1, the area of the second emission area EA2, and the area of the third emission area EA3 in a plan view may be different from each other.

In another embodiment, as shown in FIG. 6, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may be inclined by 45 degrees with respect to the first direction DR1 and the second direction DR2, and the second diagonal direction DD2 may be a direction perpendicular to the first diagonal direction DD1.

The first emission area EA1 may emit a first light, the second emission area EA2 may emit a second light, and the third emission area EA3 may emit a third light. In an embodiment, the first light may be light of a blue wavelength band, the second light may be light of a green wavelength band, and the third light may be light of a red wavelength band. For example, the blue wavelength band may be a wavelength band of light having a main peak wavelength in a range of about 370 nm to about 460 nm, the green wavelength band may be a wavelength band of light having a main peak wavelength in a range of about 480 nm to about 560 nm, and the red wavelength band may be a wavelength band of light having a main peak wavelength in a range of about 600 nm to about 750 nm.

It is illustrated in FIGS. 5 and 6 that each of the pixels PX includes three emission areas EA1, EA2, and EA3, but the disclosure is not limited thereto. For example, each of the pixels PX may include four emission areas.

The layout of the emission areas of the pixels PX is not limited to the embodiments illustrated in FIGS. 5 and 6. For example, the emission areas of the pixels PX may be disposed in a stripe structure in which the emission areas are arranged in the first direction DR1, a PenTile® structure in which the emission areas are arranged in a diamond shape, or a hexagonal structure in which the emission areas having, in a plan view, a hexagonal shape are arranged as shown in FIG. 6.

FIG. 7 is a schematic cross-sectional view illustrating an embodiment of a display panel taken along line I1-I1′ of FIG. 5.

Referring to FIG. 7, the display panel 100 may include a semiconductor backplane SBP, a light-emitting element backplane EBP, a display element layer EML, an encapsulation layer TFE, an optical layer OPL, a cover layer CVL, and a polarizing plate POL.

The semiconductor backplane SBP may include a semiconductor substrate SSUB including multiple pixel transistors PTR, multiple semiconductor insulating films covering the pixel transistors PTR, and multiple contact terminals CTE electrically connected to the pixel transistors PTR, respectively. The pixel transistors PTR may be the first to sixth transistors T1 to T6 described with reference to FIG. 4.

The semiconductor substrate SSUB may be a silicon substrate, a germanium substrate, or a silicon-germanium substrate. The semiconductor substrate SSUB may be a substrate doped with a first type impurity. Multiple well regions WA may be disposed on the top surface of the semiconductor substrate SSUB. The well regions WA may be regions doped with a second type impurity. The second type impurity may be different from the aforementioned first type impurity. For example, in case that the first type impurity is a p-type impurity, the second type impurity may be an n-type impurity. For example, in case that the first type impurity is an n-type impurity, the second type impurity may be a p-type impurity.

Each of the well regions WA may include a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on a side of the gate electrode GE, and the drain region DA may be disposed on another side of the gate electrode GE.

Each of the well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be reduced or prevented.

A first semiconductor insulating film SINS1 may be disposed on the semiconductor substrate SSUB. The first semiconductor insulating film SINS1 may be formed of silicon carbonitride (SiCN) or a silicon oxide (SiOₓ)-based inorganic film, but the disclosure is not limited thereto.

A second semiconductor insulating film SINS2 may be disposed on the first semiconductor insulating film SINS1. The second semiconductor insulating film SINS2 may be formed of a silicon oxide (SiOₓ)-based inorganic film, but the disclosure is not limited thereto.

The contact terminals CTE may be disposed on the second semiconductor insulating film SINS2. Each of the contact terminals CTE may be connected to one of the gate electrode GE, the source region SA, and the drain region DA of each of the pixel transistors PTR through a hole penetrating the first semiconductor insulating film SINS1 and the second semiconductor insulating film INS2. The contact terminals CTE may be formed of one of copper (Cu), aluminum (Al), tungsten (W), molybdenum (Mo), chromium (Cr), gold (Au), titanium (Ti), nickel (Ni), and neodymium (Nd), or an alloy thereof.

A third semiconductor insulating film SINS3 may be disposed on a side surface of each of the contact terminals CTE. The top surface of each of the contact terminals CTE may be exposed without being covered by the third semiconductor insulating film SINS3. The third semiconductor insulating film SINS3 may be formed of a silicon oxide (SiOₓ)-based inorganic film, but the disclosure is not limited thereto.

The semiconductor substrate SSUB may be replaced with a glass substrate or a polymer resin substrate including polyimide, and thin film transistors may be disposed on the glass substrate or the polymer resin substrate. The glass substrate may be a rigid substrate that does not bend, and the polymer resin substrate may be a flexible substrate that can be bent or curved.

The light-emitting element backplane EBP may include multiple conductive layers ML1 to ML8, multiple vias VA1 to VA9, and multiple insulating films INS1 to INS9. In an embodiment, the light-emitting element backplane EBP may further include the second to eighth insulating films INS2 to INS8 disposed between the first to eighth conductive layers ML1 to ML8.

The first to eighth conductive layers ML1 to ML8 may connect the contact terminals CTE exposed from the semiconductor backplane SBP to thereby implement the circuit of the first sub-pixel SP1 shown in FIG. 3. For example, the first to sixth transistors T1 to T6 may be formed in the semiconductor backplane SBP, and the connection of the first to sixth transistors T1 to T6 and the first and second capacitors C1 and C2 may be accomplished through the first to eighth conductive layers ML1 to ML8. In an embodiment, the connection between the drain region corresponding to the drain electrode of the fourth transistor T4, the source region corresponding to the source electrode of the fifth transistor T5, and the first electrode of the light-emitting element LE may be also accomplished through the first to eighth conductive layers ML1 to ML8.

The first insulating film INS1 may be disposed on the semiconductor backplane SBP. Each of the first vias VA1 may penetrate the first insulating film INS1 and be connected to the contact terminal CTE exposed from the semiconductor backplane SBP. Each of the first conductive layers ML1 may be disposed on the first insulating film INS1 and may be connected to the first via VA1.

The second insulating film INS2 may be disposed on the first insulating film INS1 and the first conductive layers ML1. Each of the second vias VA2 may penetrate the second insulating film INS2 and be connected to the exposed first conductive layer ML1. Each of the second conductive layers ML2 may be disposed on the second insulating film INS2 and may be connected to the second via VA2.

The third insulating film INS3 may be disposed on the second insulating film INS2 and the second conductive layers ML2. Each of the third vias VA3 may penetrate the third insulating film INS3 and be connected to the exposed second conductive layer ML2. Each of the third conductive layers ML3 may be disposed on the third insulating film INS3 and may be connected to the third via VA3.

A fourth insulating film INS4 may be disposed on the third insulating film INS3 and the third conductive layers ML3. Each of the fourth vias VA4 may penetrate the fourth insulating film INS4 and be connected to the exposed third conductive layer ML3. Each of the fourth conductive layers ML4 may be disposed on the fourth insulating film INS4 and may be connected to the fourth via VA4.

A fifth insulating film INS5 may be disposed on the fourth insulating film INS4 and the fourth conductive layers ML4. Each of the fifth vias VA5 may penetrate the fifth insulating film INS5 and be connected to the exposed fourth conductive layer ML4. Each of the fifth conductive layers ML5 may be disposed on the fifth insulating film INS5 and may be connected to the fifth via VA5.

A sixth insulating film INS6 may be disposed on the fifth insulating film INS5 and the fifth conductive layers ML5. Each of the sixth vias VA6 may penetrate the sixth insulating film INS6 and be connected to the exposed fifth conductive layer ML5. Each of the sixth conductive layers ML6 may be disposed on the sixth insulating film INS6 and may be connected to the sixth via VA6.

A seventh insulating film INS7 may be disposed on the sixth insulating film INS6 and the sixth conductive layers ML6. Each of the seventh vias VA7 may penetrate the seventh insulating film INS7 and be connected to the exposed sixth conductive layer ML6. Each of the seventh conductive layers ML7 may be disposed on the seventh insulating film INS7 and may be connected to the seventh via VA7.

An eighth insulating film INS8 may be disposed on the seventh insulating film INS7 and the seventh conductive layers ML7. Each of the eighth vias VA8 may penetrate the eighth insulating film INS8 and be connected to the exposed seventh conductive layer ML7. Each of the eighth conductive layers ML8 may be disposed on the eighth insulating film INS8 and may be connected to the eighth via VA8.

The first to eighth conductive layers ML1 to ML8 and the first to eighth vias VA1 to VA8 may be formed of substantially a same material. The first to eighth conductive layers ML1 to ML8 and the first to eighth vias VA1 to VA8 may be formed of one of copper (Cu), aluminum (Al), tungsten (W), molybdenum (Mo), chromium (Cr), gold (Au), titanium (Ti), nickel (Ni), and neodymium (Nd), or an alloy thereof. The first to eighth vias VA1 to VA8 may be made of substantially a same material. First to eighth insulating films INS1 to INS8 may be formed of a silicon oxide (SiOₓ)-based inorganic film, but the disclosure is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6 in the third direction DR3, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å. The thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9000 Å. The thickness of each of the seventh via VA7 and the eighth via VA8 may be approximately 6000 Å.

A ninth insulating film INS9 may be disposed on the eighth insulating film INS8 and the eighth conductive layer ML8. The ninth insulating film INS9 may be formed of a silicon oxide (SiOₓ)-based inorganic film, but the disclosure is not limited thereto.

Each of the ninth vias VA9 may penetrate the ninth insulating film INS9 and be connected to the exposed eighth conductive layer ML8. The ninth vias VA9 may be formed of one of copper (Cu), aluminum (Al), tungsten (W), molybdenum (Mo), chromium (Cr), gold (Au), titanium (Ti), nickel (Ni), and neodymium (Nd), or an alloy thereof. The thickness of the ninth via VA9 may be approximately 16500 Å.

The display element layer EML may be disposed on the light-emitting element backplane EBP. The display element layer EML may include light-emitting elements LE each including a reflective electrode layer RL, tenth and eleventh insulating films INS10 and INS11, a tenth via VA10, the first electrode AND, a light-emitting stack IL, and a second electrode CAT; and a pixel defining film PDL.

The reflective electrode layer RL may be disposed on the ninth insulating film INS9. The reflective electrode layer RL may include at least one reflective electrode RL1, RL2, RL3, and RL4. For example, the reflective electrode layer RL may include first to fourth reflective electrodes RL1, RL2, RL3, and RL4 as shown in FIG. 7.

Each of the first reflective electrodes RL1 may be disposed on the ninth insulating film INS9, and may be connected to the ninth via VA9. The first reflective electrodes RL1 may be formed of one of copper (Cu), aluminum (Al), tungsten (W), molybdenum (Mo), chromium (Cr), gold (Au), titanium (Ti), nickel (Ni), and neodymium (Nd), or an alloy thereof. For example, the first reflective electrodes RL1 may include titanium nitride (TiN).

Each of the second reflective electrodes RL2 may be disposed on the first reflective electrode RL1. The second reflective electrodes RL2 may be formed of one of copper (Cu), aluminum (Al), tungsten (W), molybdenum (Mo), chromium (Cr), gold (Au), titanium (Ti), nickel (Ni), and neodymium (Nd), or an alloy thereof. For example, the second reflective electrodes RL2 may include aluminum (Al).

Each of the third reflective electrodes RL3 may be disposed on the second reflective electrode RL2. The third reflective electrodes RL3 may be formed of one of copper (Cu), aluminum (Al), tungsten (W), molybdenum (Mo), chromium (Cr), gold (Au), titanium (Ti), nickel (Ni), and neodymium (Nd), or an alloy thereof. For example, the third reflective electrodes RL3 may include titanium nitride (TiN).

Each of the fourth reflective electrodes RL4 may be disposed on the third reflective electrode RL3. The fourth reflective electrodes RL4 may be formed of one of copper (Cu), aluminum (Al), tungsten (W), molybdenum (Mo), chromium (Cr), gold (Au), titanium (Ti), nickel (Ni), and neodymium (Nd), or an alloy thereof. For example, the fourth reflective electrodes RL4 may include titanium (Ti).

Since the second reflective electrode RL2 is an electrode that substantially reflects light from the light-emitting elements LE, the thickness of the second reflective electrode RL2 may be greater than the thickness of each of the first reflective electrode RL1, the third reflective electrode RL3, and the fourth reflective electrode RL4 in the third direction DR3. For example, the thickness of each of the first reflective electrode RL1, the third reflective electrode RL3, and the fourth reflective electrode RL4 may be approximately 100 Å, and the thickness of the second reflective electrode RL2 may be approximately 850 Å.

The tenth insulating film INS10 may be disposed on the ninth insulating film INS9. The tenth insulating film INS10 may be disposed between the reflective electrode layers RL adjacent to each other in a horizontal direction. The tenth insulating film INS10 may be formed of a silicon oxide (SiOₓ)-based inorganic film, but the disclosure is not limited thereto.

The eleventh insulating film INS11 may be disposed on the tenth insulating film INS10 and the reflective electrode layer RL. The eleventh insulating film INS11 may be formed of a silicon oxide (SiOₓ)-based inorganic film, but the disclosure is not limited thereto. The tenth insulating film INS10 and the eleventh insulating film INS11 may be an optical auxiliary layer through which light reflected by the reflective electrode layer RL passes, among light emitted from the light-emitting elements LE.

In order to match the resonance distance of the light emitted from the light-emitting elements LE in at least one of the first sub-pixel SP1, the second sub-pixel SP2, and the third sub-pixel SP3, the tenth insulating film INS10 or the eleventh insulating film INS11 may not be disposed under the first electrode AND. For example, the first electrode AND of the first sub-pixel SP1 may be disposed on (e.g., directly disposed on) the reflective electrode layer RL. The eleventh insulating film INS11 may be disposed under the first electrode AND of the second sub-pixel SP2. The tenth insulating film INS10 and the eleventh insulating film INS11 may be disposed under the first electrode AND of the third sub-pixel SP3.

In summary, the distance between the first electrode AND and the reflective electrode layer RL may be different in the first sub-pixel SP1, the second sub-pixel SP2, and the third sub-pixel SP3. For example, in order to adjust the distance from the reflective electrode layer RL to the first electrode AND according to the main wavelength of the light emitted from each of the first sub-pixel SP1, the second sub-pixel SP2, and the third sub-pixel SP3, the presence or absence of the tenth insulating film INS10 and the eleventh insulating film INS11 may be set in each of the first sub-pixel SP1, the second sub-pixel SP2, and the third sub-pixel SP3. For example, the distance between the first electrode AND and the reflective electrode layer RL in the third sub-pixel SP3 may be greater than the distance between the first electrode AND and the reflective electrode layer RL in the second sub-pixel SP2 and the distance between the first electrode AND and the reflective electrode layer RL in the first sub-pixel SP1, and the distance between the first electrode AND and the reflective electrode layer RL in the second sub-pixel SP2 may be greater than the distance between the first electrode AND and the reflective electrode layer RL in the first sub-pixel SP1. The disclosure is not limited to the above embodiments.

Although the tenth insulating film INS10 and the eleventh insulating film INS11 are illustrated in the disclosure, a twelfth insulating film disposed under the first electrode AND of the first sub-pixel SP1 may be added. The eleventh insulating film INS11 and the twelfth insulating film may be disposed under the first electrode AND of the second sub-pixel SP2, and the tenth insulating film INS10, the eleventh insulating film INS11, and the twelfth insulating film may be disposed under the first electrode AND of the third sub-pixel SP3.

Each of the tenth vias VA10 may penetrate the tenth insulating film INS10 and/or the eleventh insulating film INS11 in the second sub-pixel SP2 and the third sub-pixel SP3 and may be connected to the fourth reflective electrode RL4. The tenth vias VA10 may be formed of one of copper (Cu), aluminum (Al), tungsten (W), molybdenum (Mo), chromium (Cr), gold (Au), titanium (Ti), nickel (Ni), and neodymium (Nd), or an alloy thereof. The thickness of the tenth via VA10 in the second sub-pixel SP2 may be less than the thickness of the tenth via VA10 in the third sub-pixel SP3.

The first electrode AND of each of the light-emitting elements LE may be disposed on the tenth insulating film INS10 and connected to the tenth via VA10. The first electrode AND of each of the light-emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements LE may be formed of one of copper (Cu), aluminum (Al), tungsten (W), molybdenum (Mo), chromium (Cr), gold (Au), titanium (Ti), nickel (Ni), and neodymium (Nd), or an alloy thereof. For example, the first electrode AND of each of the light-emitting elements LE may be titanium nitride (TiN).

The pixel defining film PDL may be disposed on a portion of the first electrode AND of each of the light-emitting elements LE. The pixel defining film PDL may cover an edge of the first electrode AND of each of the light-emitting elements LE. The pixel defining film PDL may serve to partition the first emission areas EA1, the second emission areas EA2, and the third emission areas EA3.

The first emission area EA1 may be an area in which the first electrode AND, the light-emitting stack IL, and the second electrode CAT are sequentially stacked in the first sub-pixel SP1 to emit light. The second emission area EA2 may be an area in which the first electrode AND, the light-emitting stack IL, and the second electrode CAT are sequentially stacked in the second sub-pixel SP2 to emit light. The third emission area EA3 may be an area in which the first electrode AND, the light-emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on an edge of the first electrode AND of each of the light-emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOₓ)-based inorganic film, but the disclosure is not limited thereto. The first pixel defining film PDL1, the second pixel defining film PDL2, and the third pixel defining film PDL3 may each have a thickness of about 500 Å.

In case that the first pixel defining film PDL1, the second pixel defining film PDL2, and the third pixel defining film PDL3 are formed as one pixel defining film, the height of the one pixel defining film may increase, so that a first encapsulation inorganic film TFE1 may be cut off due to step coverage. Step coverage may be a ratio of the degree of thin film coated on an inclined portion to the degree of thin film coated on a flat portion. The lower the step coverage, the more likely it is that the thin film will be cut off at inclined portions.

Therefore, in order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. For example, the width of the first pixel defining film PDL1 may be greater than the width of the second pixel defining film PDL2 and the width of the third pixel defining film PDL3, and the width of the second pixel defining film PDL2 may be greater than the width of the third pixel defining film PDL3. The width of the first pixel defining film PDL1 may be a horizontal length of the first pixel defining film PDL1 defined in the first direction DR1 and the second direction DR2.

The light-emitting stack IL may include multiple intermediate layers. The light-emitting stack IL may include a first stack layer IL1, a second stack layer IL2, and a third stack layer IL3 that emit different lights. The first stack layer IL1, the second stack layer IL2, and the third stack layer IL3 may be discontinuous between adjacent sub-pixels.

The first stack layer IL1 may have a structure in which a first hole transport layer, a first organic light-emitting layer that emits the first light, and a first electron transport layer are sequentially stacked. The first stack layer IL1 may be disposed on the first electrodes AND and the pixel defining film PDL in the first emission area EA1 of the first sub-pixel SP1.

The second stack layer IL2 may have a structure in which a second hole transport layer, a second organic light-emitting layer that emits the third light, and a second electron transport layer are sequentially stacked. The second stack layer IL2 may be disposed on the first electrodes AND and the pixel defining film PDL in the second emission area EA2 of the second sub-pixel SP2.

The third hole transport layer, a third organic light-emitting layer that emits the second light, and a third electron transport layer may be sequentially stacked. The third stack layer IL3 may be disposed on the first electrodes AND and the pixel defining film PDL in the third emission area EA3 of the third sub-pixel SP3.

The second electrode CAT may be disposed on the third stack layer IL3 and the pixel defining film PDL. The second electrode CAT may be formed of a transparent conductive material (TCO) such as ITO or IZO that can transmit light or a semi-transmissive conductive material such as magnesium (Mg), silver (Ag), or an alloy of Mg and Ag. In case that the second electrode CAT is formed of a semi-transmissive conductive material, the light emission efficiency may be improved in each of the first to third sub-pixels SP1, SP2, and SP3 by forming a micro-cavity effect.

The encapsulation layer TFE may be disposed on the display element layer EML. The encapsulation layer TFE may include at least one inorganic film TFE1 and TFE2 to reduce or prevent oxygen or moisture from permeating into the display element layer EML. For example, the encapsulation layer TFE may include the first encapsulation inorganic film TFE1, and a second encapsulation inorganic film TFE2.

The first encapsulation inorganic film TFE1 may be disposed on the second electrode CAT. The first encapsulation inorganic film TFE1 may be formed as a multilayer in which one or more inorganic films including at least one of silicon nitride (SiNₓ), silicon oxy nitride (SiON), and silicon oxide (SiOₓ) are alternately stacked each other. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may be formed of titanium oxide (TiOₓ) or aluminum oxide (AlOₓ), but the disclosure is not limited thereto. The second encapsulation inorganic film TFE2 may be formed by an atomic layer deposition (ALD) process. The thickness of the second encapsulation inorganic film TFE2 may be less than the thickness of the first encapsulation inorganic film TFE1.

An organic film APL may be a layer for increasing the interfacial adhesion between the encapsulation layer TFE and the cover layer CVL. The organic film APL may be an organic film including an acrylic resin, an epoxy resin, a phenolic resin, a polyamide resin, or a polyimide resin.

The cover layer CVL may be disposed on the organic film APL. The cover layer CVL may be a glass substrate or a polymer resin.

The polarizing plate POL may be disposed on a surface of the cover layer CVL. The polarizing plate POL may be a structure for reducing or preventing visibility degradation caused by reflection of external light. The polarizing plate POL may include a linear polarizing plate and a phase retardation film. For example, the phase retardation film may be a λ/4 plate (quarter-wave plate), but the disclosure is not limited thereto.

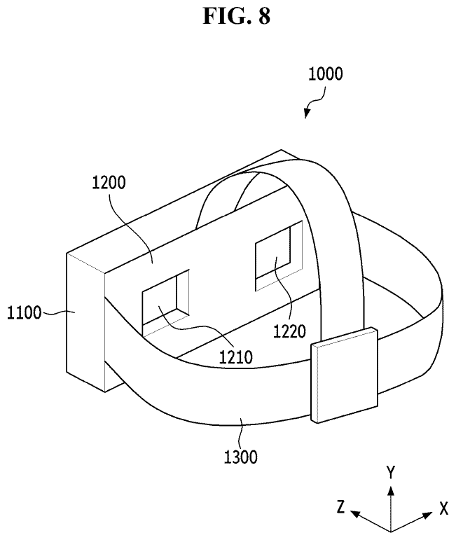

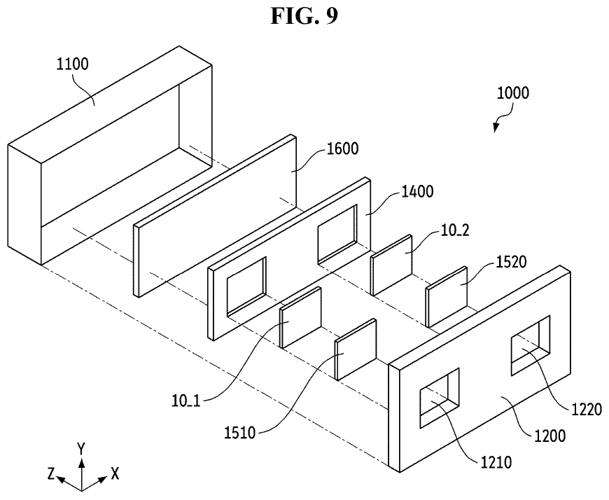

FIG. 8 is a perspective view illustrating a head mounted display according to one embodiment. FIG. 9 is an exploded perspective view illustrating an embodiment of the head mounted display of FIG. 8.

Referring to FIGS. 8 and 9, a head mounted display 1000 according to one embodiment may include a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 may provide an image to the user's left eye, and the second display device 10_2 may provide an image to the user's right eye. Since each of the first display device 10_1 and the second display device 10_2 is substantially the same as the display device 10 described in conjunction with FIGS. 1 and 2, description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 may support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source input from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. In another embodiment, the control circuit board 1600 may transmit a same digital video data DATA to the first display device 10_1 and the second display device 10_2.

The display device housing 1100 may accommodate the first display device 10_1, the second display device 10_2, the middle frame 1400, the first optical member 1510, the second optical member 1520, and the control circuit board 1600. The housing cover 1200 may cover an open surface of the display device housing 1100. The housing cover 1200 may include the first eyepiece 1210 at which the user's left eye is located and the second eyepiece 1220 at which the user's right eye is located. FIGS. 8 and 9 schematically illustrate that the first eyepiece 1210 and the second eyepiece 1220 are disposed separately, but the disclosure is not limited thereto. In another embodiment, the first eyepiece 1210 and the second eyepiece 1220 may be integral with each other.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

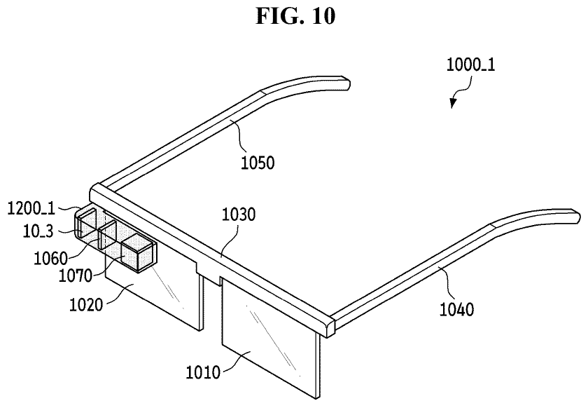

The head mounted band 1300 may secure the display device housing 1100 to the user's head such that the first eyepiece 1210 and the second eyepiece 1220 of the housing cover 1200 remain located on the user's left and right eyes, respectively. In case that the housing cover 1200 is implemented to be lightweight and compact, the head mounted display 1000 may be provided with, as shown in FIG. 10, an eyeglass frame instead of the head mounted band 1300.

In an embodiment, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 10 is a perspective view illustrating a head mounted display according to one embodiment.

Referring to FIG. 10, a head mounted display 1000_1 according to one embodiment may be an eyeglasses-type display device in which a display device housing 1200_1 is implemented in a lightweight and compact manner. The head mounted display 1000_1 according to one embodiment may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path is changed by the optical path changing member 1070. As a result, the user may view an augmented reality image, through the right eye, in which a virtual image displayed on the display device 10_3 and a real image seen through the right eye lens 1020 are combined.

FIG. 10 schematically illustrates that the display device housing 1200_1 is disposed at the right end of the support frame 1030, but the disclosure is not limited thereto. For example, the display device housing 1200_1 may be disposed at the left end of the support frame 1030, and the image of the display device 10_3 may be provided to the user's left eye. In another embodiment, the display device housing 1200_1 may be disposed at both the left and right ends of the support frame 1030, and the user may view the image displayed on the display device 10_3 through both the left and right eyes.

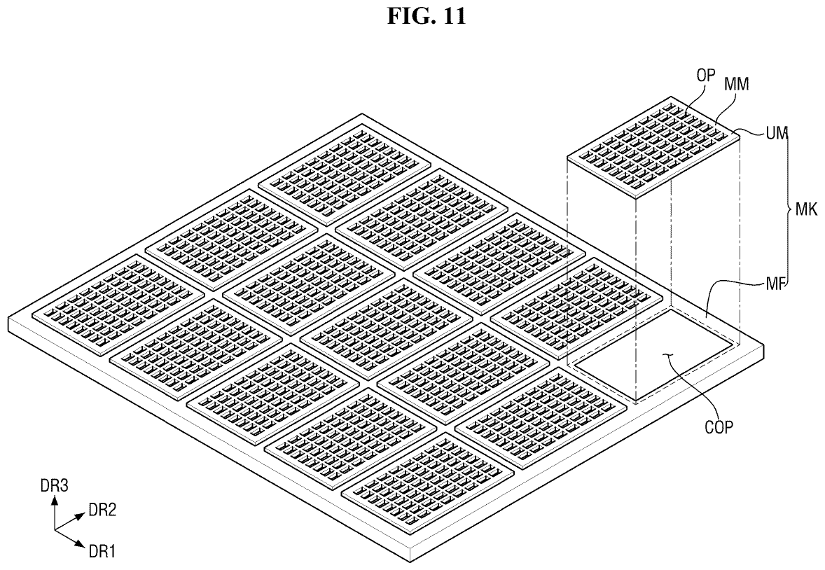

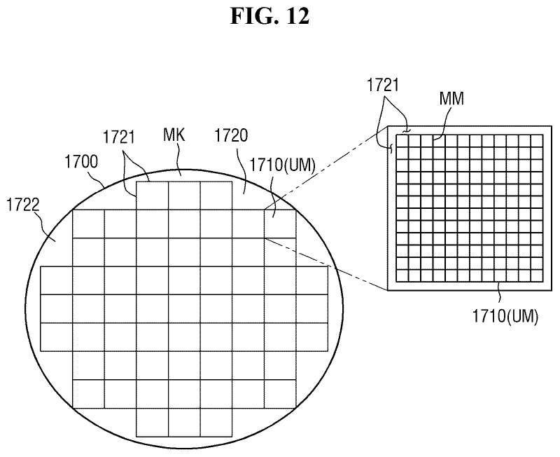

FIG. 11 is a perspective view of a mask according to one embodiment. FIG. 12 is a schematic plan view of a mask according to one embodiment. FIG. 11 shows a perspective view of a state in which one unit mask UM is separated from multiple unit masks. The mask according to one embodiment shown in FIGS. 11 and 12 may be used in the process of depositing at least a portion of the light-emitting stack IL described with reference to FIG. 7. For example, the light-emitting stack IL may be configured to emit light of different colors in each of the sub-pixels SP1, SP2, and SP3.

Referring to FIGS. 11 and 12, a mask MK according to one embodiment may be a shadow mask in which a mask membrane MM is disposed on a silicon substrate 1700. The mask MK according to one embodiment may be referred to as “silicon mask.”

According to one embodiment, the mask MK may include the silicon substrate 1700, and the mask membrane MM may be disposed on the silicon substrate 1700. The mask membrane MM may be disposed in cell regions 1710 arranged in a matrix form, and each cell region 1710 may be surrounded by a mask lip region 1721. The mask lip region 1721 may have a portion of the silicon substrate disposed therein, and may serve to support the mask membrane MM.

The mask membrane MM may be a portion of the unit mask UM disposed in each of the cell regions 1710.

The silicon substrate 1700 may include the cell regions 1710 and a mask frame region 1720 excluding the cell regions 1710. The mask frame region 1720 may include the mask lip region 1721 surrounding each cell region 1710, and an outer frame region 1722 disposed at the outermost edge of the silicon substrate 1700. A mask frame MF may be disposed in the mask frame region 1720, and the mask frame MF may include a mask lip surrounding the cell region 1710.

The mask lip region 1721 may be a region that partitions the cell regions 1710. For example, the cell regions 1710 may be arranged in a matrix form, and the mask lip disposed in the mask lip region 1721 may surround the outer edge of the mask membrane MM disposed in each cell region 1710.

A cell opening COP and the unit mask UM for masking at least a portion of the cell opening COP may be disposed in each of the cell regions 1710 of the silicon substrate 1700.

The cell openings COP may penetrate the mask frame MF along a thickness direction (e.g., the third direction DR3) of the mask MK. The cell openings COP may be formed by etching a portion of the silicon substrate 1700 from the rear direction.

Each unit mask UM may include the mask membrane MM, and the mask membrane MM may include a mask opening OP.

The mask opening OP of the mask membrane MM may be referred to as “hole” or “mask hole.” The mask openings OP may penetrate the unit masks UM along the thickness direction (e.g., the third direction DR3) of the mask MK.

A unit mask UM may be used in the deposition process of a display panel 100. In the disclosure, the term “unit mask UM” may be replaced with a term such as a mask unit UM.

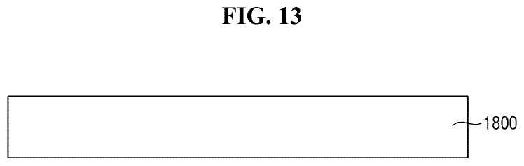

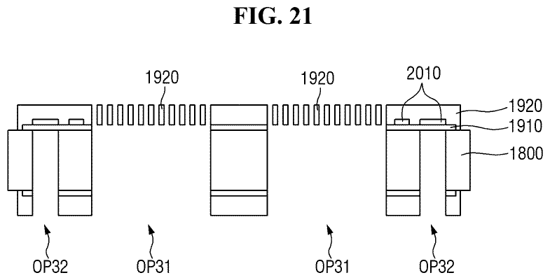

FIGS. 13 to 21 are schematic cross-sectional views illustrating a method of manufacturing a mask according to one embodiment. For example, FIG. 21 may be a schematic cross-sectional view in which a portion of the mask according to one embodiment is cut, and FIGS. 13 to 21 may be schematic diagrams sequentially illustrating a process of manufacturing the mask shown in FIG. 21.

Hereinafter, a method of manufacturing a mask according to one embodiment will be described with reference to FIGS. 13 to 15.

Referring to FIG. 13, a substrate 1800 may be provided. The substrate 1800 may include silicon (Si). The substrate 1800 may be referred to as “body substrate” or “membrane substrate,” but the disclosure is not limited thereto.

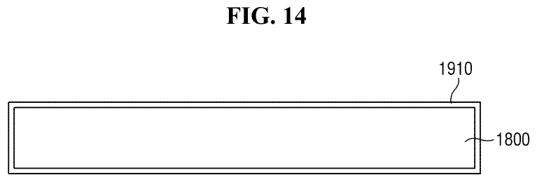

Referring to FIG. 14, a first inorganic film 1910 may be deposited to surround the surface of the substrate 1800. For example, the first inorganic film 1910 may include silicon oxide (SiOₓ).

According to one embodiment, the first inorganic film 1910 may include a material other than silicon oxide (SiOₓ). For example, the first inorganic film 1910 may include at least one of silicon (Si), silicon nitride (SiNₓ), silicon oxynitride (SiON), titanium oxide (TiOₓ), amorphous silicon (a-Si), and aluminum oxide (AlOₓ).

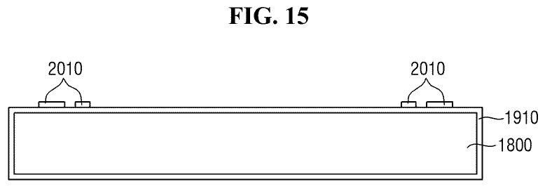

Referring to FIG. 15, an align key 2010 may be formed on the first inorganic film 1910. For example, the align key 2010 may be patterned to be aligned in a portion of a mask frame regions 1720 (see FIG. 12). The align key 2010 may include tungsten (W), but the disclosure is not limited thereto.

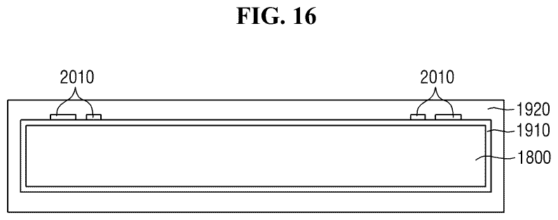

Referring to FIG. 16, a second inorganic film 1920 may be deposited on the first inorganic film 1910 including the align key 2010. The second inorganic film 1920 may include silicon nitride (SiNₓ).

According to one embodiment, the second inorganic film 1920 may include a material other than silicon nitride (SiNₓ). For example, the second inorganic film 1920 may include at least one of silicon (Si), silicon oxynitride (SiON), silicon oxide (SiOₓ), titanium oxide (TiOₓ), amorphous silicon (a-Si), and aluminum oxide (AlOₓ).

Although it is illustrated that the first inorganic film 1910 and the second inorganic film 1920 are deposited on the substrate 1800 in FIGS. 13 to 23, the disclosure is not limited thereto. For example, an inorganic film may be deposited as a single layer on the substrate 1800, and the inorganic film may include at least one of silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ). However, in the following description, an embodiment in which the first inorganic film 1910 and the second inorganic film 1920 are deposited on the substrate 1800 will be described.

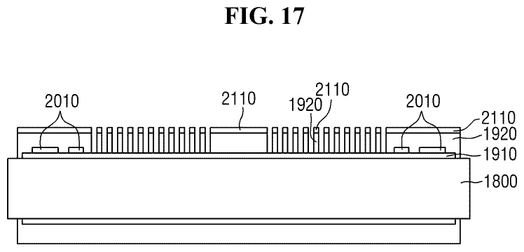

Referring to FIG. 17, a photoresist pattern 2110 may be formed on a portion of the second inorganic film 1920 disposed on the front surface of the substrate 1800, and the second inorganic film 1920 may be etched using the photoresist pattern 2110 as a mask. Accordingly, multiple openings penetrating the second inorganic film 1920 are formed.

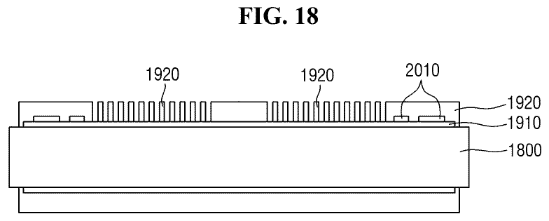

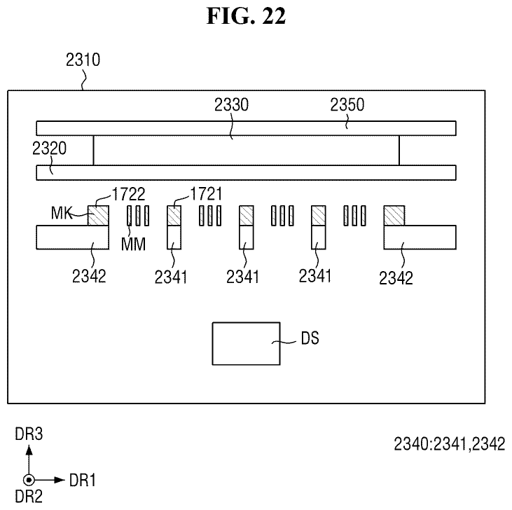

Referring to FIG. 18, the photoresist pattern 2110 may be removed. Accordingly, an inorganic film pattern from which a portion of the second inorganic film 1920 is removed may remain on the front surface of the substrate 1800. The inorganic film pattern may be formed by the second inorganic film 1920, and become a mask membrane MM (see FIG. 22) by including the openings.

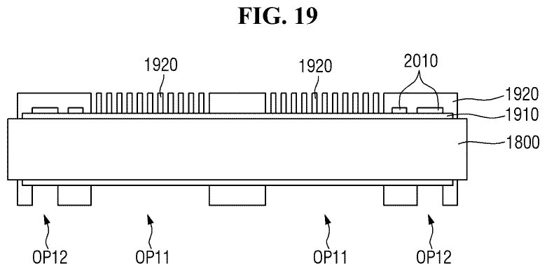

Referring to FIGS. 19 to 21, the second inorganic film 1920, the substrate 1800, and the first inorganic film 1910 may be etched from the lower direction where the rear surface of the substrate 1800 faces to expose the mask membrane MM which includes multiple first openings and is formed with the second inorganic film 1920.

As illustrated in FIG. 19, the step of exposing the mask membrane MM may include a step of forming a first cell opening OP11 which exposes a surface of the first inorganic film 1910 disposed on the rear surface of the substrate 1800 by etching the second inorganic film 1920 disposed on the rear surface of the substrate 1800. A first align opening OP12 aligned with the align key 2010 may be further formed. However, the process of forming the first align opening OP12 may not be an essential process. The process of forming the first align opening OP12 may or may not be selectively performed depending on the wavelength of light for identifying the align key 2010.

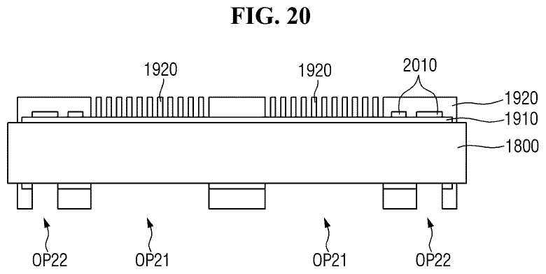

As illustrated in FIG. 20, the step of exposing the mask membrane MM may further include a step of forming a second cell opening OP21 exposing the rear surface of the substrate 1800 by etching the first inorganic film 1910 disposed on the rear surface of the substrate 1800 in the first cell opening OP11. A second align opening OP22 aligned with the align key 2010 may be further formed. However, the process of forming the second align opening OP22 may not be an essential process. The process of forming the second align opening OP22 may or may not be selectively performed depending on the wavelength of light for identifying the align key 2010.

As illustrated in FIG. 21, the step of exposing the mask membrane MM may further include a step of forming a third cell opening OP31 exposing the second inorganic film 1920, for example, the mask membrane MM, disposed on the front surface of the substrate 1800. A third align opening OP32 aligned with the align key 2010 may be further formed. However, the process of forming the third align opening OP32 may not be an essential process. The process of forming the third align opening OP32 may or may not be selectively performed depending on the wavelength of light for identifying the align key 2010.

The third cell opening OP31 illustrated in FIG. 21 may be the cell opening COP described with reference to FIG. 11.

FIG. 22 is a schematic diagram schematically illustrating a deposition apparatus according to one embodiment.

Referring to FIG. 22, a deposition apparatus according to one embodiment may include a chamber 2310, a deposition source DS disposed inside the chamber 2310, a mask MK disposed between a first substrate 2320 and the deposition source DS inside the chamber 2310, and a mask support 2340 disposed between the deposition source DS and the mask MK to support at least a portion of the mask MK.

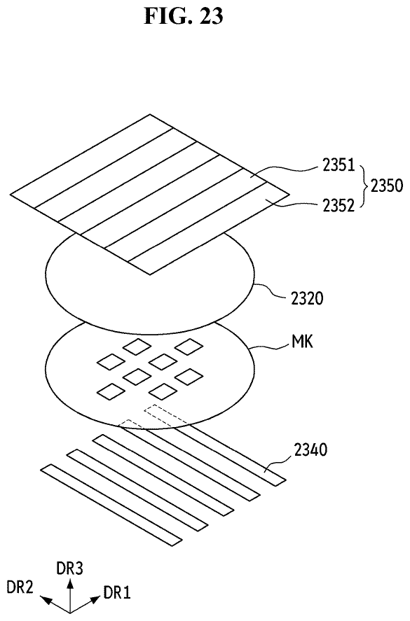

In an embodiment, the deposition apparatus may include a magnetic member 2350 disposed on the first substrate 2320. The magnetic member 2350 may include multiple magnets 2351 and 2352 (see FIG. 23) that fix the mask support 2340 with magnetic force. The magnetic member 2350 may be placed on top of a fixing member 2330 that fixes the first substrate 2320. For example, the fixing member 2330 including an electrostatic chuck for fixing the first substrate 2320 may be disposed on the first substrate 2320, and the magnetic member 2350 for fixing the mask support 2340 with magnetic force may be disposed on top of the fixing member 2330.

According to one embodiment, the mask MK may include a second substrate 1700 (see FIG. 12) including multiple cell regions 1710 (see FIG. 12) and a mask frame region 1720 (see FIG. 12) excluding the cell regions 1710, and a mask membrane MM disposed in each cell region 1710.

The first substrate 2320 illustrated in FIG. 22 may be the display panel 100 described with reference to FIGS. 1 to 10. Accordingly, the description of the first substrate 2320 may be replaced with the description of the display panel 100 with reference to FIGS. 1 to 10.

The mask MK illustrated in FIG. 22 may be a second substrate, and may include the silicon substrate 1700 or the substrate 1800 described with reference to FIGS. 13 to 22. The description of the second substrate may be replaced with the description of the silicon substrate 1700 or the substrate 1800 with reference to FIGS. 13 to 22.

The mask support 2340 may serve to support and fix the mask MK and may be disposed under the mask MK. As such mask support 2340 includes a ferromagnetic substance, the mask support 2340 may be fixed by the magnetic force of the magnetic member 2350 and support the lower portion of the mask MK. The mask support 2340 may include at least one of iron, cobalt, nickel, and an alloy thereof as a ferromagnetic substance. According to one embodiment, the ferromagnetic substance may include an Invar alloy with a very small coefficient of thermal expansion, for example, an iron-nickel alloy.

According to one embodiment, a method of manufacturing a display device 10 may include the steps below. For example, the method of manufacturing a display device 10 may include a step of disposing a first substrate 2320 on a surface of a mask MK inside the chamber 2310 of a deposition apparatus, a step of disposing a deposition source DS to face a surface of the first substrate 2320, and a step of vaporizing a deposition material included in the deposition source DS and allowing the vaporized deposition material to pass through the mask MK to be deposited on the first substrate 2320.

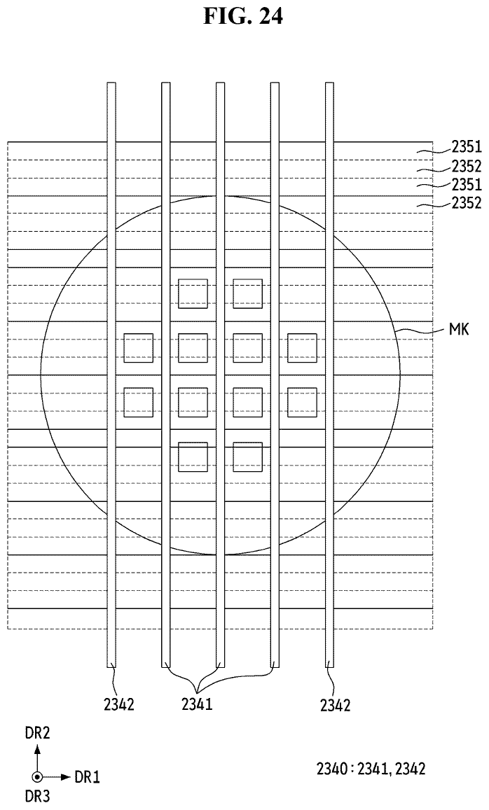

FIG. 23 is an exploded perspective view illustrating a deposition apparatus according to one embodiment. FIG. 24 is a schematic diagram of a magnetic member and a mask support according to one embodiment.

Referring to FIGS. 23 and 24, a first substrate 2320, which is a deposition substrate, may be disposed on the top (e.g., the third direction DR3) of the mask MK, and a magnetic member 2350 providing magnetic force to a mask support 2340 may be disposed on top of the first substrate 2320. The mask MK may be supported by the mask support 2340 including ferromagnetic substance.

According to one embodiment, the magnetic member 2350 may include multiple magnets 2351 and 2352 extending in a first direction DR1, and the mask support 2340 may extend in a second direction DR2 perpendicular to the first direction DR1.

The mask MK may include a silicon substrate 1700 (see FIG. 17) including multiple cell regions 1710 (see FIG. 12), an outer frame region 1722 (see FIG. 12) disposed at the outermost edge of the cell regions 1710, and a mask lip region 1721 disposed at the periphery of the cell regions 1710, and a mask membrane MM (see FIG. 22) disposed to correspond to the cell regions 1710 on the silicon substrate 1700.

The cell regions 1710 may be disposed in a matrix form, and the mask support 2340 may include multiple first magnetic lifters 2341 disposed to intersect between the cell regions 1710 and multiple second magnetic lifters 2342 disposed on both sides of the first magnetic lifters 2341 and supporting the outer frame region 1722 (see FIG. 12).

Each of the first magnetic lifters 2341 may extend in the second direction DR2, and may have a first width in the first direction DR1. Each of the second magnetic lifters 2342 may extend in the second direction DR2, has may have a first width in the first direction DR1. For example, the width of the first magnetic lifter 2341 and the width of the second magnetic lifter 2342 may be the same.

The magnetic member 2350 may include a first magnet 2351 that has a first polarity (e.g., N pole) and extends in the first direction DR1, and a second magnet 2352 that has a second polarity (e.g., S pole) and extends in the first direction DR1.

The first magnets 2351 and the second magnets 2352 may be alternatively arranged in the second direction DR2.

According to one embodiment, in case that the first magnet 2351 and the second magnet 2352 of the magnetic member 2350 are arranged to extend in the first direction DR1, the mask support 2340, which supports the mask MK and receives magnetic force from the magnetic member 2350, may extend in a direction perpendicular to the magnetic member 2350. For example, the first magnetic lifter 2341 and the second magnetic lifter 2342 of the mask support 2340 may extend in the second direction DR2 perpendicular to the first direction DR1, which is the direction the first magnet 2351 and the second magnet 2352 extend.

According to one embodiment, the support force of the mask support 2340 with respect to the mask MK may be further increased by arranging the direction in which the magnetic member 2350 extends and the direction in which the mask support 2340 extends to be perpendicular to each other. In the disclosure, sagging of the mask MK may be reduced and shadow defects or color mixing defects may be reduced by reducing the gap between the deposition substrate (i.e., the first substrate 2320) and the mask MK.

The disclosure is not limited to the mask support 2340 being in the form of a stick, as in the illustrated embodiment. For example, the mask support 2340 may include a frame not including a ferromagnetic substance. The frame of the mask support 2340 may be a circular frame or a square frame, and may be designed to be larger than the deposition area of the mask MK. Before the first magnetic lifter 2341 and the second magnetic lifter 2342 of the mask support 2340 are magnetized by a magnetic field, the frame may serve to maintain the first magnetic lifter 2341 and the second magnetic lifter 2342 in a tensioned state. Accordingly, the frame may reduce change by the sagging of mask MK.

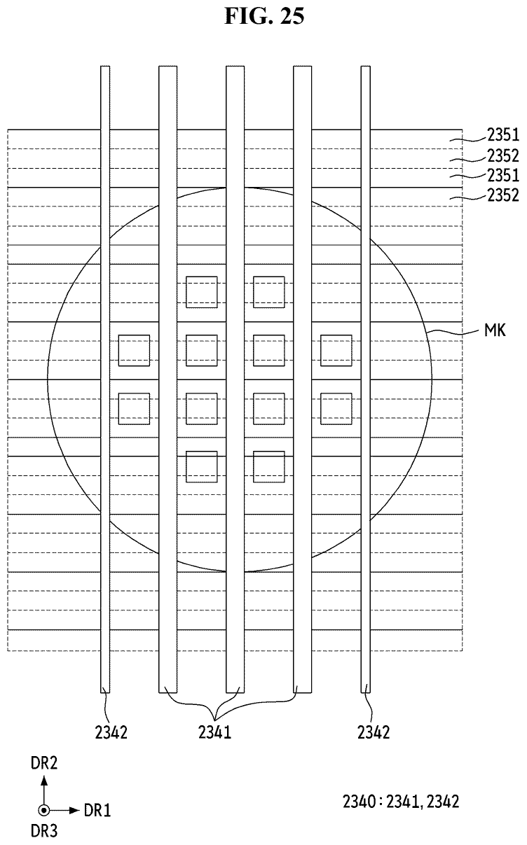

FIG. 25 is a schematic diagram of a magnetic member and a mask support according to another embodiment.

Unlike the embodiment of FIG. 24, the embodiment of FIG. 25 may be different in that the width of the first magnetic lifter 2341 and the width of the second magnetic lifter 2342 are designed to be different.

Referring to FIG. 25, each of the first magnetic lifters 2341 may extend in the second direction DR2, and may have a first width in the first direction DR1. Each of the second magnetic lifters 2342 may extend in the second direction DR2, and may have a second width smaller than the first width in the first direction DR1. For example, the width of the first magnetic lifter 2341 and the width of the second magnetic lifter 2342 may be different, and the first magnetic lifter 2341 may be designed to have relatively a greater width for the reason of supporting the mask MK.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A deposition apparatus comprising:
a deposition source;
a mask disposed between a first substrate and the deposition source;
a mask support disposed between the deposition source and the mask and supporting at least a portion of the mask; and
a magnetic member disposed on the first substrate and fixing the mask support with magnetic force, wherein
the magnetic member comprises a plurality of magnets extending in a first direction, and
the mask support extends in a second direction perpendicular to the first direction.

2. The deposition apparatus of claim 1, wherein the mask comprises:
a silicon substrate comprising a plurality of cell regions, an outer frame region disposed on an outermost edge of the plurality of cell regions, and a mask lip region disposed at a periphery of the plurality of cell regions; and
a mask membrane disposed to correspond to the plurality of cell regions on the silicon substrate.

3. The deposition apparatus of claim 2, wherein the mask membrane comprises an inorganic film.

4. The deposition apparatus of claim 3, wherein the inorganic film includes at least one of silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ), and
x is a natural number.

5. The deposition apparatus of claim 2, wherein
the plurality of cell regions are arranged in a matrix form, and the mask support comprises:
a plurality of first magnetic lifters disposed to intersect between the plurality of cell regions; and
a plurality of second magnetic lifters disposed on both sides of the plurality of first magnetic lifters and supporting the outer frame region.

6. The deposition apparatus of claim 5, wherein
each of the plurality of first magnetic lifters has a first width in the first direction, and
each of the plurality of second magnetic lifters has the first width in the first direction.

7. The deposition apparatus of claim 5, wherein
each of the plurality of first magnetic lifters has a first width in the first direction, and
each of the plurality of second magnetic lifters has a second width smaller than the first width in the first direction.

8. The deposition apparatus of claim 1, wherein the magnetic member comprises:
a first magnet having a first polarity and extending in the first direction; and
a second magnet having a second polarity and extending in the first direction.

9. The deposition apparatus of claim 8, wherein the first magnet and the second magnet are alternately arranged in the second direction.

10. The deposition apparatus of claim 1, wherein the mask support includes a ferromagnetic substance.

11. A method of manufacturing a display device, the method comprising:
placing a first substrate on a surface of a mask inside a chamber of a deposition apparatus;
placing a deposition source to face a surface of the first substrate; and
vaporizing a deposition material included in the deposition source, passing the deposition material through the mask, and depositing the deposition material on the first substrate, wherein
the deposition apparatus supports at least a portion of the mask, and comprises:
a mask support disposed between the deposition source and the mask and supporting the at least a portion of the mask; and
a magnetic member disposed on the first substrate and fixing the mask support, the magnetic member comprises a plurality of magnets extending in a first direction, and
the mask support extends in a second direction perpendicular to the first direction.

12. The method of claim 11, wherein the mask comprises:
a silicon substrate comprising a plurality of cell regions, an outer frame region disposed on an outermost edge of the plurality of cell regions, and a mask lip region disposed at a periphery of the plurality of cell regions; and
a mask membrane disposed to correspond to the plurality of cell regions on the silicon substrate.

13. The method of claim 12, wherein the mask membrane comprises an inorganic film.

14. The method of claim 13, wherein the inorganic film includes at least one of silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ), and
x is a natural number.

15. The method of claim 12, wherein
the plurality of cell regions are arranged in a matrix form, and
the mask support comprises:
a plurality of first magnetic lifters disposed to intersect between the plurality of cell regions; and
a plurality of second magnetic lifters disposed on both sides of the plurality of first magnetic lifters and supporting the outer frame region.

16. The method of claim 15, wherein
each of the plurality of first magnetic lifters has a first width in the first direction, and
each of the plurality of second magnetic lifters has the first width in the first direction. 17 The method of claim 15, wherein
each of the plurality of first magnetic lifters has a first width in the first direction, and
each of the plurality of second magnetic lifters has a second width smaller than the first width in the first direction.

18. The method of claim 11, wherein the magnetic member comprises:
a first magnet having a first polarity and extending in the first direction; and
a second magnet having a second polarity and extending in the first direction.

19. The method of claim 18, wherein the first magnet and the second magnet are alternately arranged in the second direction.

20. The method of claim 11, wherein the mask support includes a ferromagnetic substance.
